(19) United States
(12) Patent Application Publication
(10) Pub. No.: US 2007/0075348 A1
(43) Pub. Date: Apr. 5, 2007

(54) High density, high Q capacitor on top of a protective layer

(75) Inventors: Byron Lovell Williams, Plano, TX (US); Maxwell Walthour Lippitt III, Rockwall, TX (US); Darius Crenshaw, Allen, TX (US); Laurinda Ng, Plano, TX (US); Betty Mercer, Plano, TX (US); Scott Kelly Montgomery, Rowlett, TX (US); C. Matthew Thompson, Highland Village, TX (US)

Correspondence Address: TEXAS INSTRUMENTS INCORPORATED, P O BOX 655474, M/S 3999, DALLAS, TX, 75265, US

(73) Assignee: Texas Instrument Incorporated

(21) Appl. No.: 11/239,244

(22) Filed: Sep. 30, 2005

(51) Int. Cl. H01L 29/94; H01L 21/8242

(52) U.S. Cl. 257/309; 438/255; 438/398; 257/532; 438/957

(57) ABSTRACT

In accordance with the invention, there are methods for making and there is an integrated circuit comprising a semiconductor substrate comprising device elements and a metallization layer interconnecting the device elements and having an uppermost layer. The integrated circuit can also include a protective overcoat formed over the metallization layer, the protective overcoat having a plurality of patterned regions that expose portions of the metallization layer, a first conductive layer formed on the protective overcoat, and a dielectric layer formed over the first conductive layer. The integrated circuit can further include a second conductive layer formed over the dielectric layer and a plurality of sidewall spacers contacting end portions of the first conductive layer.

### RELATED APPLICATIONS

The present application is related to U.S. application Ser. No. ______ entitled “Plasma Etch Of TiW Barrier Layer for Copper Conductors,” filed Apr. 21, 2004 (Attorney Docket No. TI-36275).

### FIELD OF THE INVENTION

The subject matter of this invention relates to electronic circuits. More particularly, the subject matter of this invention relates to electronic circuits comprising high density, high quality factor capacitors.

### BACKGROUND OF THE INVENTION

Typical semiconductor devices suffer from low capacitive density due to limitations of the dielectric constant of the material used from the intralevel and interlevel dielectric layers. Moreover, because of their low dielectric constant, the materials used to form the intralevel and interlevel dielectric layers must be relatively thin. As such, they cannot be used to make high density capacitors. Typically, an additional capacitor dielectric layer needs to be employed to achieve high density capacitors. Still further, the dielectric materials and metal layers used in conventional semiconductor devices are typically not thick enough to create sidewall topography for high sidewall density.

Another drawback of the conventional devices is that they have a low quality factor, also called “Q”. One reason for the low-Q is that conventional devices use high resistance metals or polysilicon to connect to inductors. Moreover, the metal lines have a high resistance because they are relatively thin. Another reason for high resistance is that aluminum is typically used as the interconnect metal. Aluminum has a higher resistivity than, for example, copper. High resistance of the interconnect to the capacitor can also negatively impact phase noise in voltage controlled oscillator applications as well as insertion loss.

In some cases, high voltage controlled capacitance (VCC) in capacitors is due to the high resistivity of materials used for the bottom and top electrodes. One typical high resistivity capacitor electrode material is polycrystalline silicon (“polysilicon”). Polysilicon is prone to depletion under biasing, which can result in reduced overall capacitance and an increase in VCC.

Conventional silicon on chip (“SOC”) devices typically form capacitor electrodes using the gate polysilicon layer and/or the metal layers that serve as interconnects. In both cases, however, the close proximity of the capacitor to the substrate can cause an increase in the parasitic capacitance of the capacitor.

Accordingly, the present invention solves these and other problems of the prior art to provide a high density, high-Q capacitor for a semiconductor device.

### SUMMARY OF THE INVENTION

In accordance with the invention, there is an integrated circuit comprising a semiconductor substrate comprising device elements and a metallization layer interconnecting the device elements and having an uppermost layer. The integrated circuit can also include a protective overcoat formed over the metallization layer, the protective overcoat having a plurality of patterned regions that expose portions of the metallization layer, a first conductive layer formed on the protective overcoat, and a dielectric layer formed over the first conductive layer. The integrated circuit can further include a second conductive layer formed over the dielectric layer and a plurality of sidewall spacers contacting end portions of the first conductive layer.

According to another embodiment of the present invention, there is a method of making an integrated circuit. The method can comprise forming a semiconductor substrate comprising device elements and a metallization layer interconnecting the device elements and having an uppermost layer, forming a protective overcoat over the metallization layer, and forming a plurality of patterned regions in the protective overcoat that expose portions of the metallization layer. The method can also include forming a first conductive layer formed on the protective overcoat, forming a dielectric layer formed over the first conductive layer, forming a second conductive layer formed over the dielectric layer, and forming sidewall spacers contacting end portions of the first conductive layer.

According to yet another embodiment of the present invention, there is another method of making a capacitor. The method can comprise forming a semiconductor substrate comprising device elements and a metallization layer interconnecting the device elements and having an uppermost layer, forming a protective overcoat over the metallization layer, and forming a plurality of patterned regions in the protective overcoat that expose portions of the metallization layer. The method can also comprise forming a first conductive layer formed on the protective overcoat, forming a dielectric layer formed over the first conductive layer, and forming a second conductive layer over the dielectric layer and filling at least one of the patterned regions.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1A-1G depict a schematic illustration of an exemplary semiconductor device according to an embodiment of the present invention.

FIG. 2A-2G depict another schematic illustration of an exemplary semiconductor device in accordance with another embodiment of the present invention.

FIG. 3 shows a graph of capacitance versus pitch according to various embodiments of the present invention.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Although the exemplary methods and variations disclosed herein are described below as a series of acts, the present invention is not limited by the specific ordering of the acts. For example, some acts may occur in different orders and/or concurrently with other acts or events apart from those illustrated and/or described herein, in accordance with the invention. In addition, not all illustrated steps may be required to implement a methodology in accordance with the present invention.

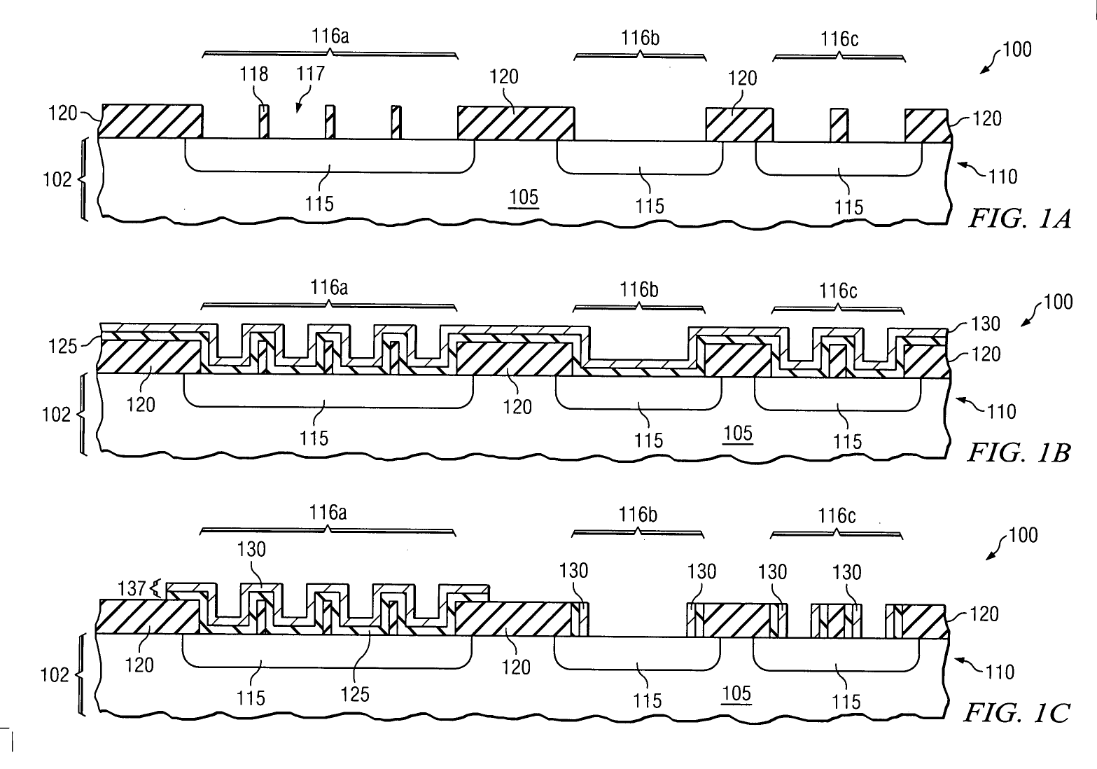

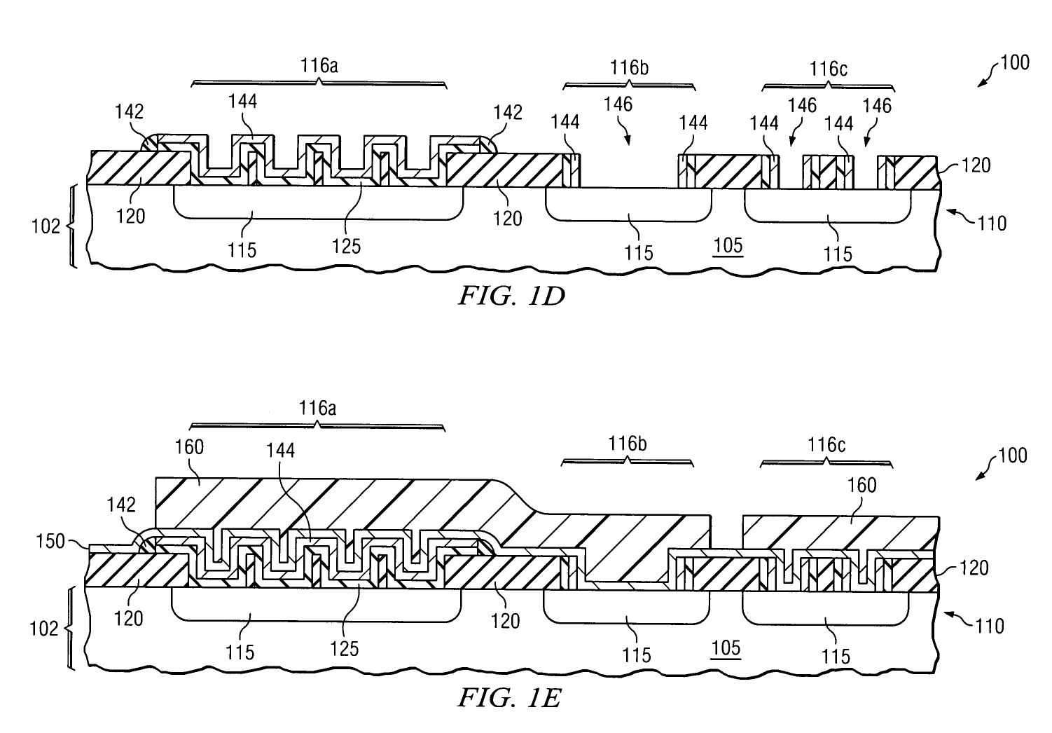

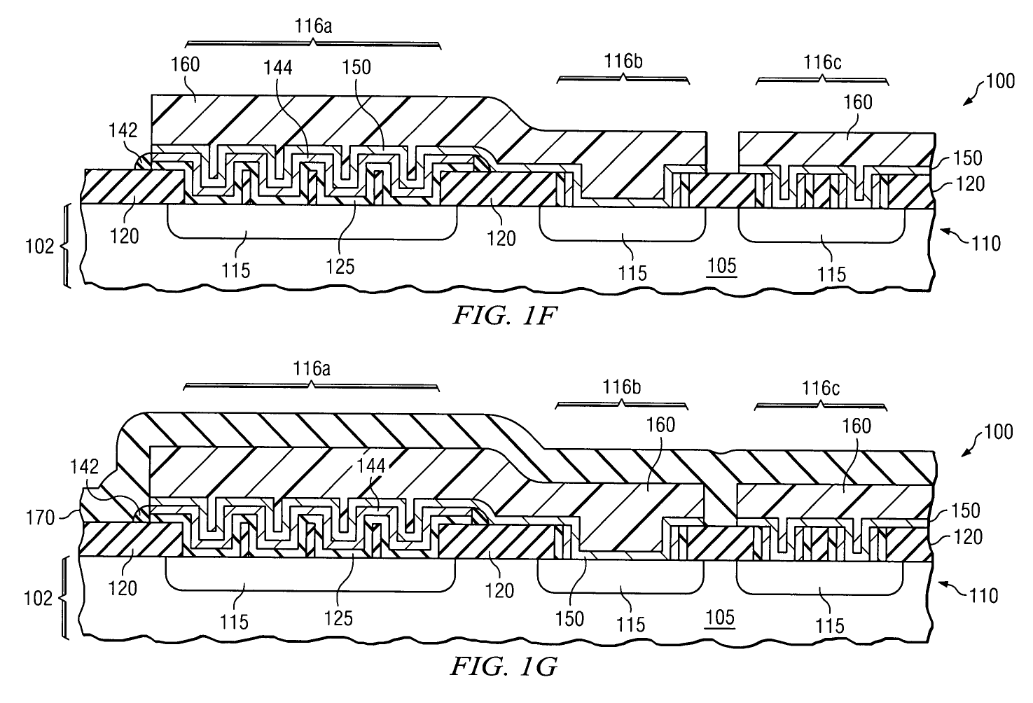

FIG. 1A provides a schematic illustration of an exemplary semiconductor device 100 having a substrate 102 processed through formation of a metallization layer. The substrate 102 includes a semiconductor substrate 105 and a topmost metallization layer 110. In addition to device elements, the substrate may include one or more metallization layers that are not illustrated. The metal forms conductive lines and eventually contacts other device structures. The metallization layer 110 includes a metal 115 separated by an interlevel dielectric (ILD), silicon, or some other material. According to various embodiments, the metal 115 can be aluminum. In other embodiments, the metal 1 15 can be copper. The metallization layer 110 can contain one or multiple layers of metallization, as may be appreciated by one of ordinary skill in the art. In some cases the metal 115 can be a top level metal region, such as a metal-2 layer or a metal-3 layer of a device. According to various embodiments, the metal 115 can be a thick metal layer used as a low resistive path for routing and power bussing. In various embodiments, the metal 115 can have a thickness from about 0.1 μm to about 1.0 μm, and in some embodiments from about 0.3 μm to about 0.6 μm.

As shown in FIG. 1A, semiconductor device 100 can also include a protective overcoat 120. A protective overcoat can be an insulating layer that provides electrical isolation and mechanical protection for underlying structures. It can also provide chemical and ion protection. The protective overcoat can comprise one or more layers. Typical layer materials include, but are not limited to, silicon nitride, silicon oxynitride, silicon oxide, PSG (Phospho-Silicate Glass), organic polymers such as polyimide, other materials, either alone or in combination. Silicon nitride has a high strength and silicon oxynitride can be used where transparency is need, such as, for example, to allow UV memory erase. The overall thickness of the protective layer can be from about 0.5 μm to about 2.0 μm, and in some cases, from about 0.8 μm to about 1.5 μm.

As shown in FIG. 1A, the protective layer 120 is patterned. The protective layer 120 can be patterned by a lithographic process. Lithography refers to processes for pattern transfer between various media. For example, a radiation sensitive coating, such as, for example, a photoresist (“resist”) can be formed on the surface. The resist is patterned by selectively exposing the resist through a mask. The exposed areas of the coating become either more or less soluble than the unexposed areas, depending on the type of resist. A solvent developer is used to remove the less soluble areas leaving the pattern resist.

The protective overcoat material is etched using the patterned resist as a mask to transfer the pattern to the protective overcoat. Etch processes include plasma etching, reactive ion etching, wet etching, and combinations thereof. According to various embodiments, the etch process can be highly anisotropic and can give vertical sidewalls to the patterned features. Subsequently, the remaining resist can be removed.

Referring again to FIG. 1A, generally, three patterned regions 116a-c are shown. A high density, high-Q capacitor bottom electrode can be formed in patterned region 116a, a top electrode connection can be formed in patterned region 116b, and patterned region 116c can serve as exemplary vias. According to various embodiments, pattered region 116a can further comprise a plurality of holes 117 so as to form fingers 118. The fingers 118 can provide increased surface area, including sidewall surface area, on which the capacitor can be formed. As will be understood by one of ordinary skill in the art, increasing the surface area can increase the capacitance of the capacitor.

According to various embodiments, the holes 117 can have a diameter from about 0.2 μm to about 2.0 μm, and in some cases, from about 0.5 μm to about 1.5 μm, and in still further cases, from about 0.8 μm to about 1.2 μm. Moreover, the pitch of the holes 117 can be from about 0.5 μm to about 3.0 μm, and in some cases from about 1.0 μm to about 2.5 μm, and in still further cases, from about 1.8 μm to about 2.2 μm.

After forming and patterning the protective overcoat 120, the semiconductor substrate is covered by a first electrode layer 125, shown in FIG. 1B. According to various embodiments, the first electrode layer can comprise titanium, titanium nitride, tungsten, tantalum, tantalum nitride, chromium, gold, platinum, molybdenum, or an alloy thereof. In certain embodiments the first electrode layer 125 can comprise TiW or TaN. The first electrode layer can serve as the bottom electrode for a capacitor as well as serving as a barrier layer. For example, the first electrode layer 125 can limit unwanted elements from diffusing into or out of underlying layers. According to various embodiments, the first electrode layer 125 can conformally cover the semiconductor substrate. Moreover, the first electrode layer 125 can contact the metal 115. Diffusion can be from, for example, aluminum or copper. The first electrode layer 125 can also provide good adhesion between metals. The thickness of the first electrode layer 125 can be from about 0.1 μm to about 0.5 μm, and in some cases from about 0.2 μm to about 0.3 μm.

In patterned region 116a, the first electrode layer 125 electrically contacts metal 115, which can server as the bottom electrode electrical connection. In patterned regions 116b and 116c, where there is no capacitor, the first electrode layer can enhance electrical contact and can also serve as a barrier layer. Moreover, in patterned region 116b, the first electrode layer 125 also contacts the metal 115, which can serve as the top electrode contact.

The first electrode layer 125 can be formed by any suitable method including, for example, physical vapor deposition, chemical vapor deposition, electroless plating, electroplating, or sputtering. Generally, chemical or physical vapor deposition can be used to allow a uniform coating of small holes or vias with steep sidewalls. Although the first electrode layer 125 is described in the present example over the substrate, in another embodiment, the first electrode layer 125 may be formed only where needed for the capacitor.

As also shown in FIG. 1B, a capacitor dielectric 130 is deposited over the first electrode layer 125. According to various embodiments, the capacitor dielectric 130 can comprise silicon nitride, silicon dioxide, ONO, Hi K dielectrics or polyimides. The thickness of the capacitor dielectric 130 can be from about 0.01 μm to about 100 μm, and in some cases from about 0.15 μm to about 0.30 μm. The capacitor dielectric 130 can be formed by any suitable method including, for example, physical vapor deposition, chemical vapor deposition, LPCVD, APCVD, PECVD, and spin on materials. Further, placing the capacitor above the protective overcoat layer, the device will accept more exotic electric materials that will not negatively impact the transistor parameters. According to various embodiments, the capacitor dielectric 130 can conformally cover the semiconductor substrate.

Referring to FIG. 1C, portions of the first electrode layer 125 and the capacitor dielectric layer 130 above the protective layer 120 have been removed. According to various embodiments, the portions of the first electrode layer 125 and the capacitor dielectric layer 130 can be removed using a patterned photoresist. For example, a photoresist material can be deposited over the semiconductor substrate. The photoresist can be exposed using a mask. Subsequently, portions of the first electrode layer 125 and the capacitor dielectric layer 130 can be removed by various etching techniques as will be known to one of ordinary skill in the art. Any remaining photoresist can then be removed from the device. The now patterned first electrode layer 125 and the patterned capacitor dielectric layer 130 terminate at ends 137.

Referring to FIG. 1D, after removing the photoresist, a layer of dielectric material can be deposited over the semiconductor substrate. Exemplary dielectric materials can include silicon dioxide, such as from tetraethyl orthosilicate (TEOS), silicon nitride, SiH₄ or combinations thereof. A non-isotropic etch can be performed to form sidewall spacers 142 adjacent to ends 137 as well as adjacent to sides 144 of vias 146. Alternatively, sidewall spacers 142 can be formed from the capacitor dielectric 130. According to various embodiments, etching of the dielectric layer can stop upon exposure of the protective overcoat 120.

The sidewall spacers 142 prevent the top plate of the inductor from shorting to the top plate of the inductor. Moreover, it improves the reliability of the device by completely isolating both electrodes. For example, the sidewall spacers 140 can insulate the first electrode layer 125 from additional layers formed thereover, which will be described below. Without the sidewalls spacers, shorting can occur at ends 137.

Referring to FIG. 1E, a seed layer 150 can be deposited over the semiconductor substrate. According to various embodiments, the seed layer can include a barrier layer to prevent diffusion, from copper, for example, into the protective overcoat 120. The seed layer 150 can comprise, for example an uppermost portion comprising copper and a lower portion comprising TiW, Ti/TiN, or Ta/TaN. The uppermost portion of copper can be from about 0.1 μm to about 0.5 μm thick, and in some cases from about 0.2 μm to about 0.3 μm thick. The seed layer 150 can be deposited by any suitable means including, for example, sputter deposition. It should be appreciated that seed layer 150 in the present example is illustrated as a double layer, however, single layer seed layers 150 may be employed and are contemplated by the present invention. According to various embodiments, the seed layer 125 can conformally cover the semiconductor substrate.

Also shown in FIG. 1E, a metal top layer 160 can be deposited over the seed layer 150. According to various embodiments, the metal top layer 160 can be relatively thick. For example, the metal top layer 160 can be thicker than about 1.0 μm. Moreover, it can be formed from a copper layer, such as an electroplated copper layer. As shown in FIG. 1E, the metal top layer 160 can fill the remaining portion or spaces between the plurality of fingers 117, as well as the remaining portion or space in the patterned regions 116b and 116c.

Referring to FIG. 1F, the seed layer 150 can be etched to separate the various layers, such as in etched regions 116a and 116b from patterned regions 116c. Thus, a high density, high-Q capacitor is formed in patterned region 116a and a capacitor contact is formed in patterned region 116b. Moreover, patterned region 116c can comprise electrical contacts to various device components.

FIG. 1G shows a protective film 170 formed over the semiconductor device 100. According to various embodiments, the protective film can be an insulator, such as an oxide or nitride.

In the case where the seed layer comprises an uppermost portion of copper and a lower portion of TiW, two etch steps can be used. For example, a wet etch can be used to etch the copper layer followed by a dry etch to etch the TiW.

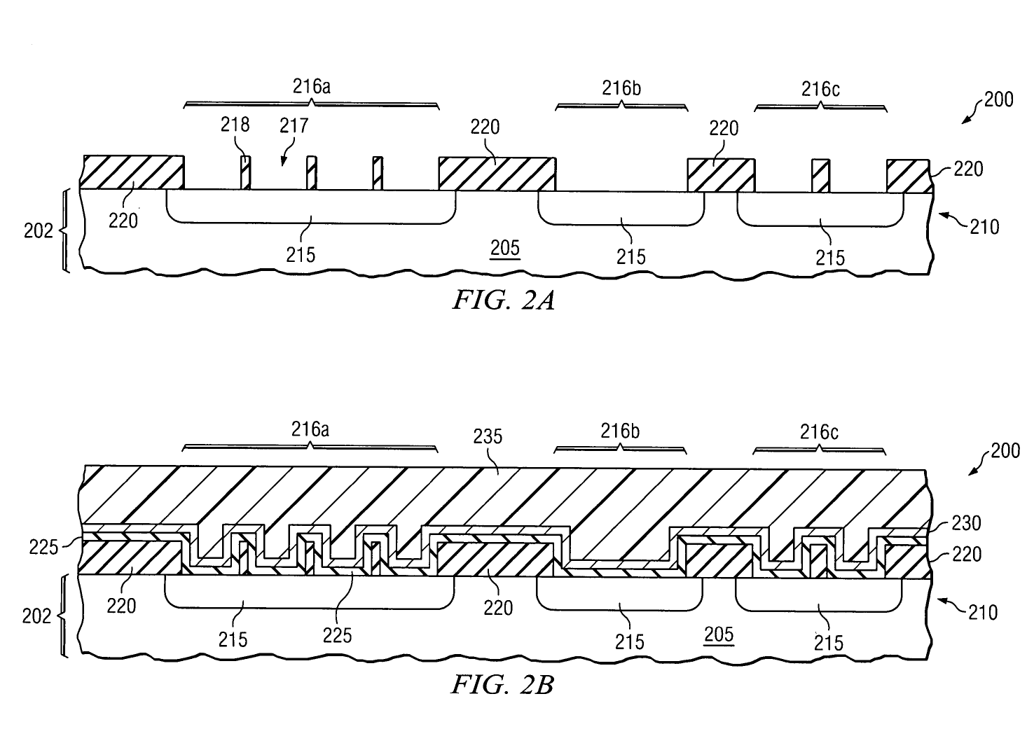

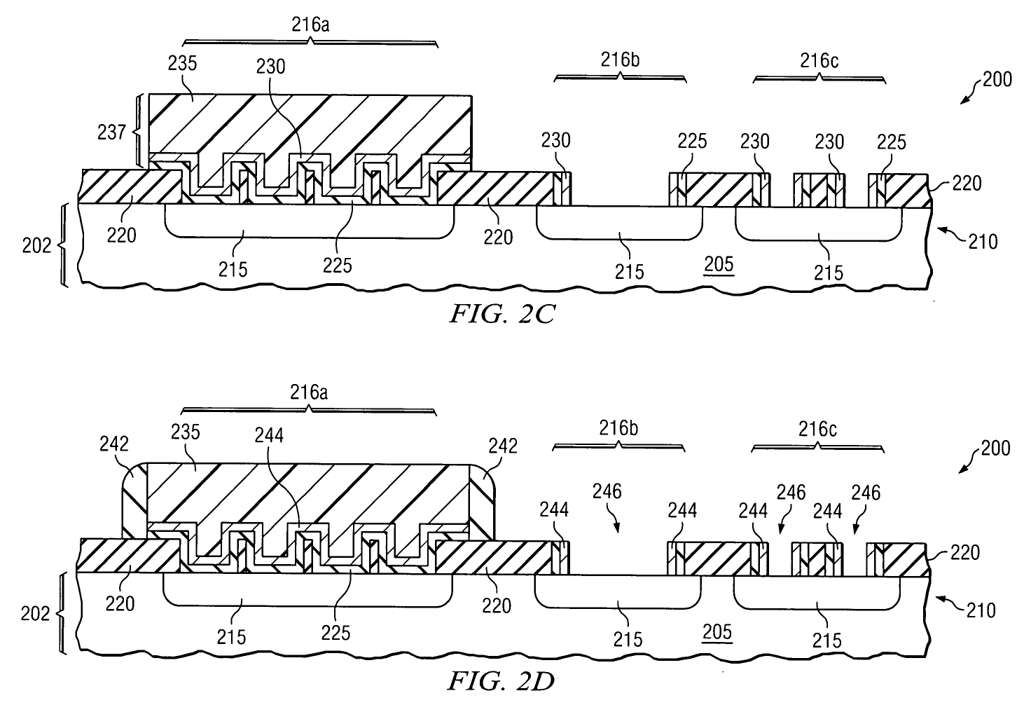

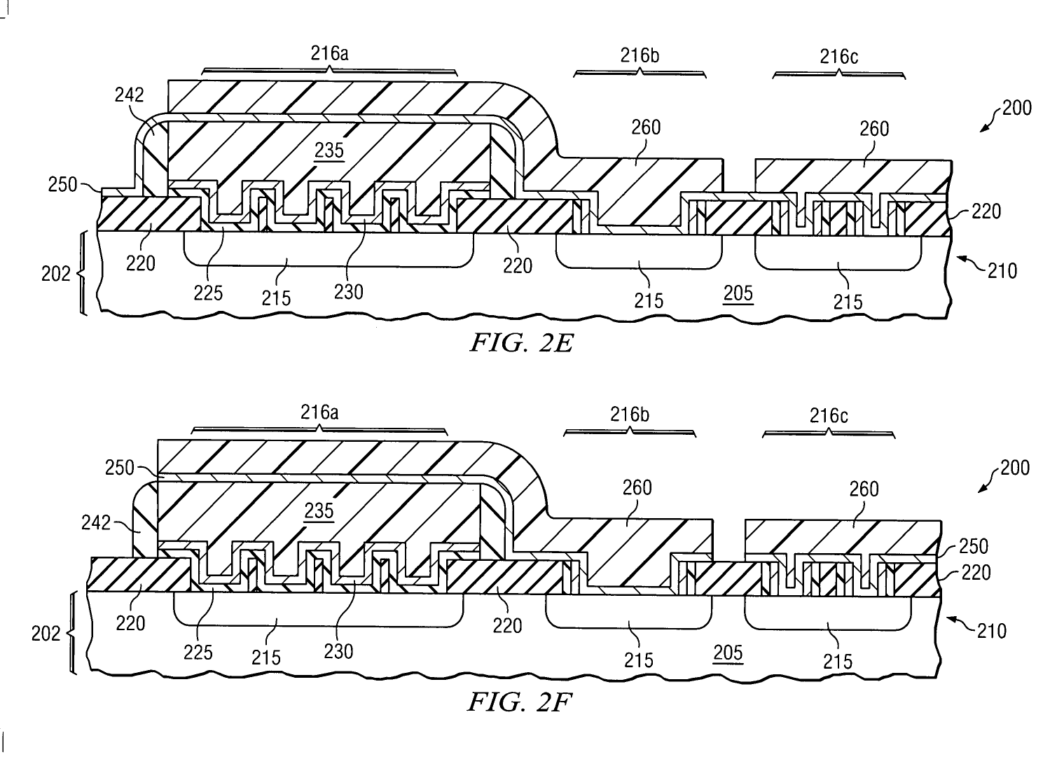

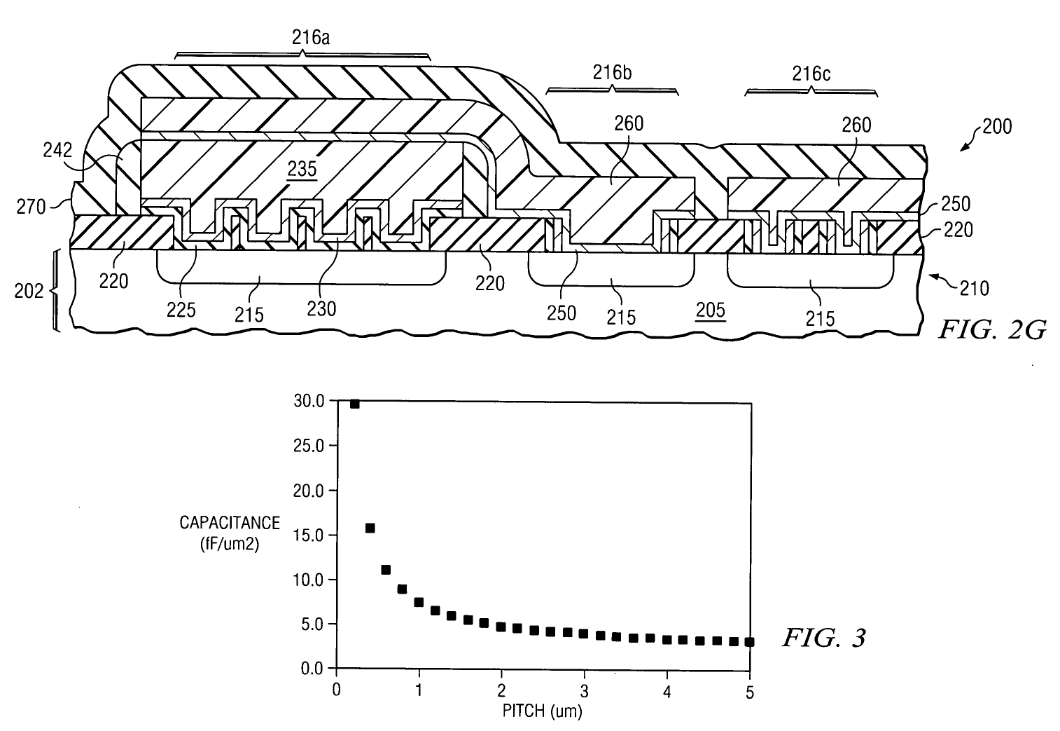

FIGS. 2A-2G depict another embodiment for forming a capacitor above a protective overcoat. Referring to FIG. 2A, an exemplary semiconductor device 200 is shown having a substrate 202 processed through formation of a metallization layer. The substrate 202 includes a semiconductor substrate 205 and a topmost metallization layer 210. In addition to device elements, the substrate may include one or more metallization layers that are not illustrated. The metal forms conductive lines and eventually contacts other device structures. The metallization layer 210 includes a metal 215 separated by an interlevel dielectric (ILD), silicon, or some other material. According to various embodiments, the metal 215 can be aluminum. In other embodiments, the metal 215 can be copper. The metallization layer 210 can contain one or multiple layers of metallization, as may be appreciated by one of ordinary skill in the art. In some cases, the metal 215 can be a top level metal region, such as a metal-2 layer or a metal-3 layer of a device. According to various embodiments, the metal 215 can be a thick metal layer used as a low resistive path for routing and power bussing. In various embodiments, the metal 215 can have a thickness from about 0.1 μm to about 1.0 μm, and in some embodiments from about 0.3 μm to about 0.6 μm.

Semiconductor device 200 shown in FIG. 2A also includes a protective overcoat 220. A protective overcoat can be an insulating layer that provides electrical isolation and mechanical protection for underlying structures. It can also provide chemical and ion protection. The protective overcoat can comprise one or more layers. Typical layer materials include silicon nitride, silicon oxynitride, silicon oxide, PSG (Phospho-Silicate Glass), organic polymers such as polyimide, other materials, either alone or in combination. Silicon nitride has a high strength and silicon oxynitride can be used where transparency is need, such as, for example, to allow UV memory erase. The overall thickness of the protective layer can be from about 0.5 μm to about 2.0 μm, and in some cases, from about 0.8 μm to about 1.5 μm.

As shown in FIG. 2A, the protective layer 220 is patterned. The protective layer 220 can be a resist patterned by a lithographic process. The resist is patterned by selectively exposing the resist through a mask. The exposed areas of the coating become either more or less soluble than the unexposed areas, depending on the type of resist. A solvent developer is used to remove the less soluble areas leaving the pattern resist.

The protective overcoat material is etched using the patterned resist as a mask to transfer the pattern to the protective overcoat. Etch processes include plasma etching, reactive ion etching, wet etching, and combinations thereof. According to various embodiments, the etch process can be highly anisotropic and can give vertical sidewalls to the patterned features. Subsequently, the remaining resist can be removed.

Referring again to FIG. 2A, generally, three patterned regions 216a-c are shown. A high density, high-Q capacitor can be formed in patterned region 216a, a top electrode connection can be formed in patterned region 216b, and patterned region 216c can serve as exemplary vias. According to various embodiments, pattered region 216a can further comprise a plurality of holes 217 so as to form fingers 218. The fingers 218 can provide increased surface area, including sidewall surface area, on which the capacitor can be formed. As will be understood by one of ordinary skill in the art, increasing the surface area can increase the capacitance of the capacitor.

According to various embodiments, the holes 217 can have a diameter from about 0.2 μm to about 2.0 μm, and in some cases, from about 0.5 μm to about 1.5 μm, and in still further cases, from about 0.8 μm to about 1.2 μm. Moreover, the pitch of the holes 217 can be from about 0.5 μm to about 3.0 μm, and in some cases from about 1.0 μm to about 2.5 μm, and in still further cases, from about 1.8 μm to about 2.2 μm.

After forming and patterning the protective overcoat 220, the semiconductor substrate is covered by a first electrode layer 225, shown in FIG. 2B. According to various embodiments, the first electrode layer can comprise titanium, titanium nitride, tungsten, tantalum, tantalum nitride, chromium, gold, platinum, molybdenum, or an alloy thereof. In certain embodiments the first electrode layer 225 can comprise TiW or TaN. The first electrode layer can serve as the bottom electrode for a capacitor as well as serving as a barrier layer. For example, the first electrode layer 225 can limit unwanted elements from diffusing into or out of underlying layers. Moreover, the first electrode layer 225 can contact the metal 215. Diffusion can be from, for example, aluminum or copper. The first electrode layer 225 can also provide good adhesion between metals. The thickness of the first electrode layer 225 can be from about 0.1 μm to about 0.5 μm, and in some cases from about 0.2 μm to about 0.3 μm.

In patterned region 216a, the first electrode layer 225 electrically contacts metal 215, which can serve as the bottom electrode electrical connection. In patterned regions 216b and 216c, where there is no capacitor, the first electrode layer can enhance electrical contact and can also serve as a barrier layer. Moreover, in patterned region 216b, the first electrode layer 225 also contacts the metal 215, which can serve as the top electrode contact.

The first electrode layer 225 can be formed by any suitable method including, for example, physical vapor deposition, chemical vapor deposition, electroless plating, electroplating, or sputtering. Generally, chemical or physical vapor deposition can be used to allow a uniform coating of small holes or vias with steep sidewalls. Although the first electrode layer 225 is described in the present example over the substrate, in another embodiment, the first electrode layer 225 may be formed only where needed for the capacitor.

As also shown in FIG. 2B, a capacitor dielectric 230 is deposited over the first electrode layer 225. According to various embodiments, the capacitor dielectric 230 can comprise silicon nitride, silicon dioxide, ONO, Hi K dielectrics or polyimides. The thickness of the capacitor dielectric 230 can be from about 0.01 μm to about 100 μm, and in some cases from about 0.10 μm to about 0.30 μm, and in still further cases, from about 0.13 μm to about 0.15 μm. The capacitor dielectric 230 can be formed by any suitable method including, for example, physical vapor deposition, chemical vapor deposition, LPCVD, APCVD, PECVD, and spin on materials. Further, placing the capacitor above the protective overcoat layer, the device will accept other electrically conductive materials that will not negatively impact the transistor parameters.

A second electrode layer 235 can be formed over the capacitor dielectric 230. According to various embodiments, the second electrode layer 235 can comprise tungsten, Al, or electroplated copper. As shown in FIG. 2B, the second electrode layer 235 can plug or fill the remaining portions or spaces between the plurality of fingers 217. According to various embodiments, the second electrode layer 235 can also fill the remaining portion or space in the patterned regions 216b and 216c. In some embodiments, the second electrode layer 235 need not be planarized to a high degree. This can reduce processing time and cost by not incurring a chemical mechanical. processing step.

Referring to FIG. 2C, portions of the first electrode layer 225, the capacitor dielectric layer 230, and the second electrode layer 235 above the protective layer 220 have been removed. Moreover, in some embodiments, the second electrode layer 235 can be removed from the patterned regions 216b and 216c. According to various embodiments, the portions of the first electrode layer 225, the capacitor dielectric layer 230, and the second electrode layer 235 can be removed using a patterned photoresist. For example, a photoresist material can be deposited over the semiconductor substrate. The photoresist can be exposed using a mask. Subsequently, portions of the first electrode layer 225, the capacitor dielectric layer 230, and the second electrode layer 235 can be removed by various etching techniques as will be known to one of ordinary skill in the art. Any remaining photoresist can then be removed from the device. The now patterned first electrode layer 225, the patterned capacitor dielectric layer 230, and the patterned second electrode layer 235 terminate at ends 237.

Referring to FIG. 2D, after removing the photoresist, a layer of dielectric material can be deposited over the semiconductor substrate. Exemplary dielectric materials can include silicon dioxide, such as from tetraethyl orthosilicate (TEOS), silicon nitride, silicon dioxide, ONO or polyimides, or combinations thereof. A non-isotropic etch can be performed to form sidewall spacers 242 adjacent to ends 237 as well as adjacent to sides 244 of vias 246. According to various embodiments, etching of the dielectric layer can stop upon exposure of the protective overcoat 220.

The sidewall spacers 242 prevent the top plate of the inductor from shorting to the top plate of the inductor. Moreover, it improves the reliability of the device by completely isolating both electrodes. For example, the sidewall spacers 240 can insulate the first electrode layer 225 from the second electrode layer 235. Without the sidewalls spacers, shorting can occur between the first electrode layer 225 and the second electrode layer 235 at ends 237.

Referring to FIG. 2E, a seed layer 250 can be deposited over the semiconductor substrate. According to various embodiments, the seed layer can include a barrier layer to prevent diffusion, such as from copper, into the protective overcoat 220. The seed layer 250 can comprise, for example an uppermost portion comprising copper and a lower portion comprising TiW, Ti/TiN, or Ta/TaN. The uppermost portion of copper can be from about 0.1 μm to about 0.5 μm thick, and in some cases from about 0.2 μm to about 0.3 μm thick. The seed layer 250 can be deposited by any suitable means including, for example, sputter deposition. It should be appreciated that seed layer 250 in the present example is illustrated as a double layer, however, single layer seed layers 250 may be employed and are contemplated in the present invention.

Also shown in FIG. 2E, a metal top layer 260 can be deposited over the seed layer 250. According to various embodiments, the metal top layer 260 can be relatively thick. For example, the metal top layer 260 can be thicker than about 1.0 μm. Moreover, it can be formed from a copper layer, such as an electroplated copper layer. As shown in FIG. 2E, the metal top layer 260 can fill the spaces between the plurality of the remaining space in the patterned regions 216b and 216c.

Referring to FIG. 2F, the seed layer 250 can be patterned to separate the various layers, such as in patterned regions 216a and 216b from patterned regions 216c. Thus, a high density, high-Q capacitor is formed in patterned region 216a and a capacitor contact is formed in patterned region 216b. Moreover, patterned region 216c can comprise electrical contacts to various device components.

FIG. 2G shows a protective film 270 formed over the semiconductor device 200. According to various embodiments, the protective film can be an insulator, such as an oxide or nitride.

In the case where the seed layer comprises an uppermost portion of copper and a lower portion of TiW, two etch steps can be used. For example, a wet etch can be used to etch the copper layer followed by a dry etch to etch the TiW.

By forming the capacitor in the protective overcoat layer, the capacitor density can be increased. Using the protective overcoat layer to support the capacitor can increase the sidewall area and thus increase the effective area of the capacitor. According to various embodiments, the capacitor density can be from about 1.0 fF/um² to about 10 fF/um². Further, as mentioned above, placing the capacitor above the protective overcoat layer, the device will accept more exotic electric materials that will not negatively impact the transistor parameters. Still further, placing forming the capacitor over the protective overcoat layer can reduce unwanted parasitics. Moreover, forming the capacitor over the protective overcoat can better utilize precious chip real estate. In particular, the capacitor can be formed proximate to the space of large area components where only bondpads and power bussing is done.

According to various embodiments, the capacitors described herein can exhibit a capacitance of from about 1.0 fF/mm² to about 10 fF/mm².

Reducing the pitch of the holes that form the capacitor fingers can increase the capacitance. This can be seen from the graph in FIG. 3. FIG. 3 shows a graph of capacitance versus pitch. For example, holes formed according to the present invention with a pitch of 2.0 μm can provide a capacitance of 5.0 fF/mm².

According to various embodiments, the capacitance ranges can be achieved regardless of the voltage condition. In certain embodiments the capacitance ranges can be achieved at about 1 MHz. In addition, various capacitance ranges disclosed herein are achieved using silicon nitride as the capacitor dielectric. Significantly enhanced capacitance ranges, however, can be achieved using Hi-K materials.

According to various embodiments, the device Q can be improved that can lead to lower phase noise and lower insertion loss. Improved device Q can be obtained by using the thick (>6 μm) Cu final layer of metal as a low resistance connection to the capacitor. Further, devices can be made having a lower linear voltage capacitance by using the thick (>6 μm) Cu as part of the top plate of the capacitor. This allows for the capacitor to be used in highly linear analog circuits.

Various embodiments use a thick Cu plating process. Moreover, the capacitor can be placed above the protective overcoat where capacitors are normally not found. This allows for placement of various passive components, such as capacitors, inductors, and resistors above the protective overcoat. Moreover, using the thickness of the protective overcoat for creating trenches for additional sidewall capacitance is achieved.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An integrated circuit comprising:
a semiconductor substrate comprising device elements and a metallization layer interconnecting the device elements and having an uppermost layer;
a protective overcoat formed over the metallization layer, the protective overcoat having a plurality of patterned regions that expose portions of the metallization layer,
a first conductive layer formed on the protective overcoat;
a dielectric layer formed over the first conductive layer;
a second conductive layer formed over the dielectric layer; and
a plurality of sidewall spacers contacting end portions of the first conductive layer.

2. The integrated circuit according to claim 1, wherein at least one of the patterned regions forms a capacitor and wherein the at least one of the patterned regions comprises a plurality of holes separated by fingers formed from the protective overcoat.

3. The integrated circuit according to claim 1 further comprising:
a third conductive layer disposed between the first conductive layer and the second conductive layer.

4. The integrated circuit according to claim 2 further comprising:
a third conductive layer disposed between the first conductive layer and the second conductive layer, wherein the second metal layer fills at least a portion of the holes separated by the fingers formed from the protective overcoat.

5. The integrated circuit according to claim 2, wherein the second conductive layer fills a remaining portion of the holes separated by the fingers formed from the conductive overcoat.

6. The integrated circuit according to claim 3, wherein the third conductive layer is a seed layer.

7. The integrated circuit according to claim 1, wherein the metallization layer comprises copper or aluminum.

8. The integrated circuit according to claim 4, wherein the second conductive layer comprises copper.

9. The integrated circuit according to claim 2, wherein the capacitor has a capacitance of at least 1.0 fF/mm².

10. The integrated circuit according to claim 4, wherein the holes are positioned at a pitch from about 0.5 μm to about 3.0 μm.

11. A method of making an integrated circuit, the method comprising:
forming a semiconductor substrate comprising device elements and a metallization layer interconnecting the device elements and having an uppermost layer;
forming a protective overcoat over the metallization layer;
forming a plurality of patterned regions in the protective overcoat that expose portions of the metallization layer;
forming a first conductive layer formed on the protective overcoat;
forming a dielectric layer formed over the first conductive layer;
forming a second conductive layer formed over the dielectric layer; and
forming sidewall spacers contacting end portions of the first conductive layer.

12. The method of making an integrated circuit according to claim 11 further comprising:
forming a plurality of holes separated by fingers formed from the protective overcoat in at least one of the patterned regions.

13. The method of making an integrated circuit according to claim 11 further comprising:
forming a third conductive layer over the dielectric layer prior to forming the second conductive layer.

14. The method of making an integrated circuit according to claim 11, wherein the third conductive layer is a seed layer.

15. The method of making an integrated circuit according to claim 11, wherein the first conductive layer comprises copper or aluminum.

16. A method of making a capacitor, the method comprising:
forming a semiconductor substrate comprising device elements and a metallization layer interconnecting the device elements and having an uppermost layer;
forming a protective overcoat over the metallization layer;
forming a plurality of patterned regions in the protective overcoat that expose portions of the metallization layer;
forming a first conductive layer formed on the protective overcoat;
forming a dielectric layer formed over the first conductive layer; and
forming a second conductive layer over the dielectric layer and filling at least one of the patterned regions.

17. The method of making a capacitor according to claim 16 further comprising:
forming sidewall spacers contacting end portions of the first conductive layer.

18. The method of making a capacitor according to claim 16 further comprising:
forming a plurality of holes separated by fingers formed from the protective overcoat in at least one of the patterned regions.

19. The method of making a capacitor according to claim 16 further comprising:
forming a third conductive layer over the dielectric layer prior to forming the second conductive layer.

20. The method of making a capacitor according to claim 16, wherein the capacitor has a capacitance of at least 1.0 fF/mm².
